(19) United States
(12) Patent Application Publication
(10) Pub. No.: US 2010/0020862 A1
(43) Pub. Date: Jan. 28, 2010

(54) INPUT CONTROL CIRCUIT FOR THE SUMMER OF A DECISION FEEDBACK EQUALIZER

(75) Inventor: Yung-Chow Peng, Hsinchu (TW)

Correspondence Address: K&L Gates LLP;IP Docketing, 630 Hansen Way, Palo Alto, CA, 94304, US

(73) Assignee: TAIWAN SEMICONDUCTOR MANUFACTURING CO., LTD.

(21) Appl. No.: 12/180,390

(22) Filed: Jul. 25, 2008

(51) Int. Cl. H03H 7/30

(52) U.S. Cl. 375/233

(57) ABSTRACT

This invention discloses a tap circuit in a summer of a decision feedback equalizer (DFE), the tap circuit comprises a differential pair of received signal lines, a current source having a magnitude being substantially proportional to a tap weight coupled between a first node and a ground, a plurality of NMOS transistors controllably coupled the current source to either one of the received signal lines, and DFE data signals and DEF logic sign signals being coupled only to the gates of the plurality of NMOS transistors, wherein tap circuit can operate at low supply voltage without losing speed.

### BACKGROUND

The present invention relates generally to integrated circuit (IC) design, and, more particularly, to a decision feedback equalizer design.

As semiconductor process technology progresses, IC chips can operate at greater speed and offer greater processing power. This places a greater demand for data rate of I/O signals, so that maximum system-level performance can be realized. I/O signals may be transmitted in interchip links such as central processing unit (CPU) memory applications, and long-range backplane or coax links that arise in systems such as scalable multiple-processor servers and high-speed routers/switches. The long-range applications are particularly challenging to realize robust high-speed I/O transmission due to the combined effects of increased transmission line loss, crosstalk, and signal distortion arising from reflections that occur as data rates move into the microwave frequency range of operation and beyond.

To enable reliable signal transmissions, the I/O core architecture can employ some form of line equalization. A common approach to equalization for data rate up to 3-4 Gb/s is feed-forward equalization, or FFE, at the transmitter, which predistorts the signal such that it is recovered at the receiver with a desired shape suitable for reliable data detection. Another form of equalizer is the decision feedback equalizer, or DFE, which operates by subtracting the intersymbol interference, or ISI, arising from previously detected data symbols from the symbol currently being received.

FIG. 1 is a block diagram illustrating a conventional receiver 100 employing a DFE. The receiver 100 comprises a signal amplifier 110, a summer 120 for a DFE 140, a analog-to-digital sampler 130, a demultiplexer module 150, a DFE logic module 160, a clock data recovery (CDR) logic module 170 and a phase interpolator module 175. The DFE logic module 160 extracts tap weights from outputs of the demultiplexer module 150. Tap weights are combined with DEF signals at a multiplier 122 and then summed up by adder 125. Both the multiplier 122 and the adder 125 are part of the summer 130. The CDR logic module 170 and phase interpolator module 175 obtain timing information for the sampler 130. In summary, the DFE sums a compensation value with the received signal as a function of prior sliced data decisions and associated tap weights.

FIG. 2 is a schematic diagram illustrating a conventional circuit implementation of the summer 120 which comprises k number of taps, where k is an integer. Outputs, in the form of a differential pair, of the amplifier 110 are connected to inputs of the sampler 130 through nets SN and SP. A plurality of feedback tap blocks 202[1] to 202[k], where k is an integer, is connected to the nets SN and SP. The summer 120 serves to sum up feedback tap with the received signal.

Referring to FIG. 2, the circuit structure of the taps 202[1] to 202[k] are identical, but signals and tap weights are different for each tap block. Using tap block 202[1] as an example, complimentary data signals DataP[1] and DataN[1] are generated by the DFE module 140 of FIG. 1, and complimentary sign signals SgnP[1] and SgnN[1] are generated by the DFE logic module 160 of FIG. 1. The tap weight[1] is represented by a predetermined current source 206[1]. A pair of NMOS transistors 212[1] and 214[1] determines the tap weight[1] is added to either the net SN or the net SP. When the NMOS transistor 212[1] is turned on, current is drawn from the net SP, i.e., the received signal at net SP is modified by the tap weight[1]. Similarly, when the NMOS transistor 214[1] is turned of, current is drawn from the net SN, i.e., the received signal at net SN is modified by the tap weight[1]. The NMOS transistors 212[1] and 214[1] are controlled by the complimentary data signals DataP[1] and DataN[1] and by the complimentary sign signals SgnP[1] and SgnN[1]. When the signal SgnP[1] is at a logic high, and the signal SgnN[1] is at a logic low, PMOS transistors 224[1] and 226[1] are turned on. At the same time, if the signal DataP[1] is at the logic high and the signal DataN[1] is at the logic low, the NMOS transistor 212[1] is turned on and the NMOS transistor 214[1] is turned off. Similarly, when the signal SgnP[1] is at the logic low, and the signal SgnN[1] is at the logic high, PMOS transistors 222[1] and 228[1] are turned on. At the same time, if the signal DataP[1] is at the logic high and the signal DataN[1] is at the logic low, the NMOS transistor 214[1] is turned on and the NMOS transistor 212[1] is turned off. In this way, a desired tap weight in the form of the magnitude of the current source 206[1] is fed back to the received signals at either the net SN or the net SP. However, the data signal DataP[1] or DataN[1] need to pass the transmission gate PMOS transistor 222[1], 224[1], 226[1] or 228[1] to control the NMOS transistor 212[1] or 214[1]. The transmission gate PMOS transistor has a voltage drop across its source and drain. For deep submicron processes, a power supply voltage may be very low which causes the voltage drop by the PMOS transistor 222[1], 224[1], 226[1] or 228[1] to be comparable to the power supply voltage. In this case, the summer circuit 120 may be slow down or even fail to operate properly. As such, what is desired is a summer of a DFE that can operate at low power supply voltage without sacrificing speed.

### SUMMARY

This invention discloses a tap circuit in a summer of a decision feedback equalizer (DFE), the tap circuit comprises a differential pair of received signal lines, a current source having a magnitude being substantially proportional to a tap weight coupled between a first node and a ground, a plurality of NMOS transistors controllably coupled the current source to either one of the received signal lines, and DFE data signals and DEF logic sign signals being coupled only to the gates of the plurality of NMOS transistors, wherein tap circuit can operate at low supply voltage without losing speed.

The construction and method of operation of the invention, however, together with additional objectives and advantages thereof will be best understood from the following description of specific embodiments when read in connection with the accompanying drawings.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore non-limiting, embodiments illustrated in the drawings, wherein like reference numbers (if they occur in more than one view) designate the same elements. The invention may be better understood by reference to one or more of these drawings in combination with the description presented herein. It should be noted that the features illustrated in the drawings are not necessarily drawn to scale.

FIG. 1 is a block diagram illustrating a conventional receiver employing a decision feedback equalizer (DFE).

FIG. 2 is a schematic diagram illustrating a conventional circuit implementation of the summer of the DFE of FIG. 1.

FIG. 3 is a schematic diagram illustrating a summer of a DFE according to a first embodiment of the present invention.

FIG. 4 is a schematic diagram illustrating an alternative summer of a DFE according to a second embodiment of the present invention.

### DESCRIPTION

The present invention discloses a summer circuit for a decision feedback equalizer (DFE) that can operate at low power supply voltage without sacrificing either speed or circuit complexity.

As described in the above background section, a summer of a DFE is to add DFE corrections to a received signal by pulling weighed currents from either the positive or negative leg of a differential amplifier output.

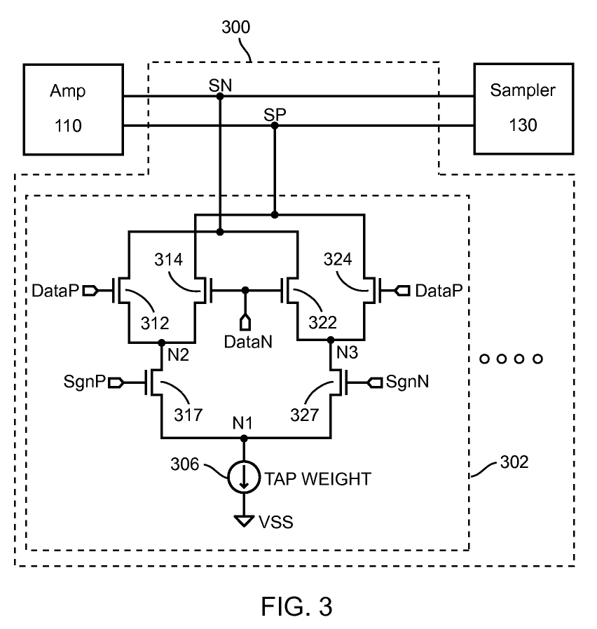

FIG. 3 is a schematic diagram illustrating a summer 300 of a DFE according to a first embodiment of the present invention. The summer 300 corrects the differential received signals at nets SN and SP by pulling a current either at the net SN or the net SP by a plurality of taps, although only one 302 of such taps is shown in FIG. 3. The tap 302 comprises a current source 306 with a magnitude determined by a tap weight. The current source 306 is coupled between a node N1 and a ground VSS. Herein the term “coupled” means directly connected or connected through another component, but where that added another component supports the circuit function.

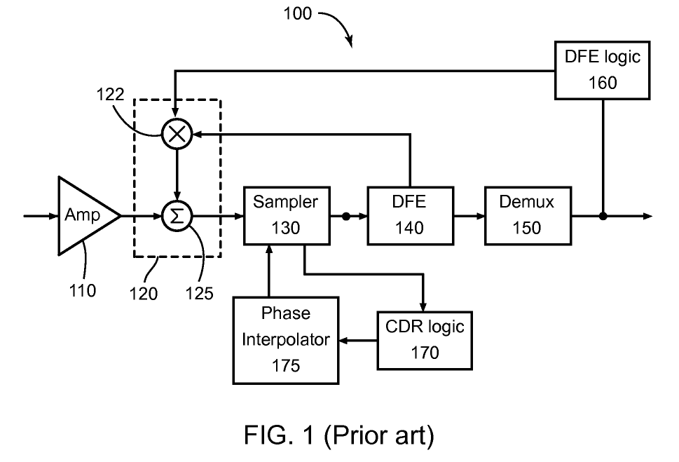

Referring again to FIG. 3, a plurality of NMOS switching transistors 312˜327 couple the node N1 to the nets SN and SP selectively. Specifically, the NMOS transistor 317 is coupled between the node N1 and a node N2. The NMOS transistor 327 is coupled between the node N1 and a node N3. The NMOS transistor 312 is coupled between the node N2 and the net SN. The NMOS transistor 314 is coupled between the node N2 and the net SP. The NMOS transistor 322 is coupled between the node N3 and the net SN. The NMOS transistor 324 is coupled between the node N3 and the net SP. A gate of the NMOS transistor 317 is coupled to a sign signal SgnP. A gate of the NMOS transistor 327 is coupled to a sign signal SgnN. Gates of the NMOS transistors 312 and 324 are coupled to a data signal DataP. Gates of the NMOS transistors 314 and 322 are coupled to a data signal DataN. As described in the above background section, the sign signal SgnP and SgnN are complimentary to each other and are generated by the DFE logic module 160 of FIG. 1. The data signal DataP and DataN are complimentary to each other and are generated by the DFE module 140 of FIG. 1.

In operations, when the sign signals SgnP and SgnN are at the logic high and low, respectively, the NMOS transistor 317 is on and the NMOS transistor 327 is off. At the same time, if the data signals DataP and DataN are at the logic high and low, respectively, the NMOS transistors 312 and 324 are on and the NMOS transistor 314 and 322 are off. As a result, the current source 306 is switched to the net SN. With the sign signals SgnP and SgnN remain at the logic high and low, respectively, and the data signals DataP and DataN are at the logic low and high, respectively, the NMOS transistors 317 and the NMOS transistor 314 are on, thus the current source 306 is switched to the net SP.

On the other hand, when the sign signals SgnP and SgnN are at the logic low and high, respectively, the NMOS transistor 317 is off and the NMOS transistor 327 is on. At the same time, if the data signals DataP and DataN are at the logic high and low, respectively, the NMOS transistors 312 and 324 are on and the NMOS transistor 314 and 322 are off. As a result, the current source 306 is switched to the net SP. With the sign signals SgnP and SgnN remain at the logic low and high, respectively, and the data signals DataP and DataN are at the logic low and high, respectively, the NMOS transistors 327 and the NMOS transistor 322 are on, thus the current source 306 is switched to the net SN.

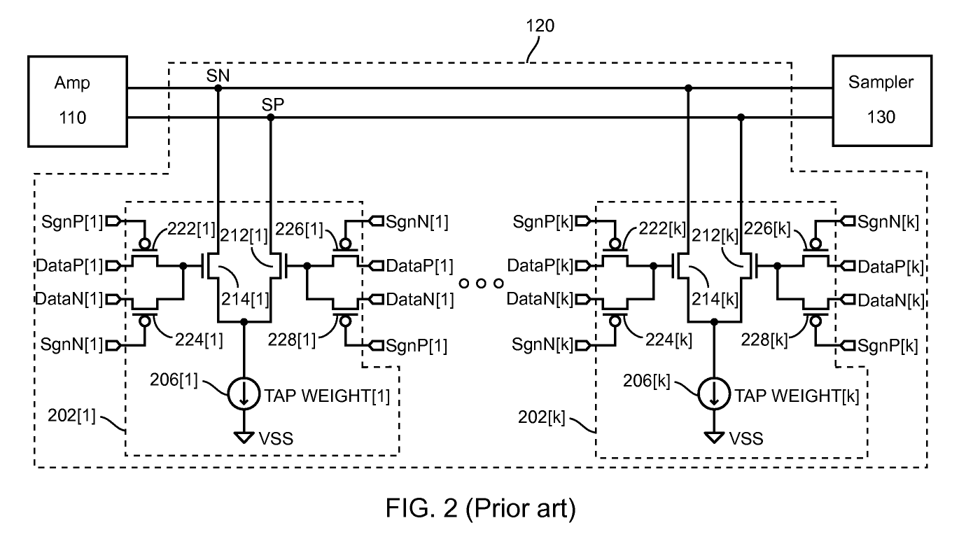

Referring again to FIG. 3, as both the sign signals, SgnP and SgnN, and the data signals, DataP and DataN, are coupled to the gates of the switching NMOS transistors, the tap 302 can operate at very low supply voltage and switch faster than the tap 202[1] of FIG. 2 where the data signals, DataP[1] and DataN[1], are coupled to the drains of transmission gate NMOS transistors 222[1] and 224[1], respectively, or to the drains of the transmission gate NMOS transistors 226[1] and 228[1], respectively.

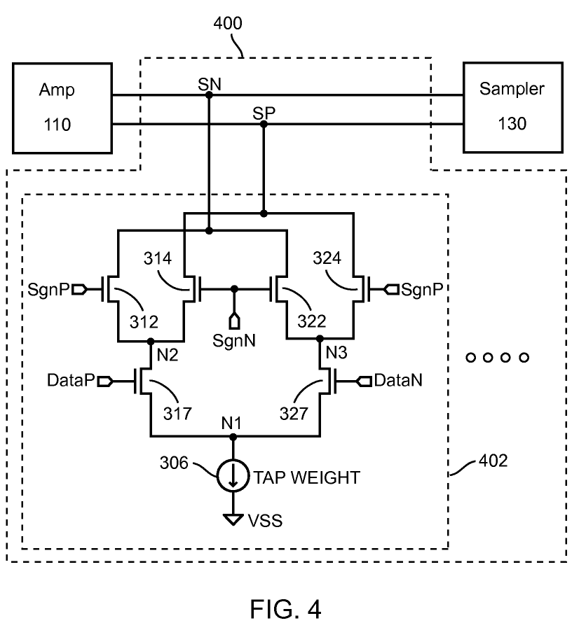

FIG. 4 is a schematic diagram illustrating an alternative summer 400 of a DFE according to a second embodiment of the present invention. The circuit structure of the summer 400 is identical to the summer 300 of FIG. 3, but the signals are coupled to gates of different transistors. Specifically, the data signals, DataP and DataN, are coupled to the gates of the NMOS transistors 317 and 327, respectively. The sign signal SgnP is coupled to both the NMOS transistors 312 and 324. The sign signal SgnN is coupled to both the NMOS transistors 314 and 322. Because the sign signal is a quasi-constant signal during an operation, while the data signals change from time to time depend on the received signal. The gate loading of the data signal DataP or DataN is one gate for the tap 400 of FIG. 4, while two gates for the tap 300 of FIG. 3. Therefore, the transition speed of the tap 400 is further improved as being compared to the tap 300 of FIG. 3.

Referring back to FIGS. 3 and 4, in summary, the NMOS transistors 312˜327 constitute an input control circuit for the tap of the summer 300 or 400. The control signals, i.e., the data signals, DataP and DataN, and the sign signals, SgnP and SgnN, are all coupled to the gates of the NMOS transistors 312˜327, thus the tap of the summer 300 or 400 can operate at low power supply voltage without losing switching speed.

Although the disclosed summer circuit 300 or 400 is constructed by NMOS transistors with a current source coupled to the ground, a skilled artisan would appreciate that the summer circuit can also be constructed by PMOS transistors with a current source coupled to a high voltage power supply.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A tap circuit in a summer of a decision feedback equalizer (DFE), the tap circuit comprising:
a first and a second net carrying a differential pair of received signals;
a correction source coupled between a first node and a first power supply voltage, the correction source having a magnitude being substantially proportional to a tap weight;
a first switching transistor with a source and a drain coupled between the first node and a second node, respectively;
a second switching transistor with a source and a drain coupled between the first node and a third node, respectively;
a third switching transistor with a source and a drain coupled between the second node and the first net, respectively;
a fourth switching transistor with a source and drain coupled between the second node and the second net, respectively;
a fifth switching transistor with a source and drain coupled between the third node and the first net, respectively;
a sixth switching transistor with a source and drain coupled between the third node and the second net, respectively;
a first and second control signals coupled to gates of the first and second switching transistors, respectively, the first and second control signal being complimentary to each other;
a third control signal coupled to gates of the third and sixth switching transistors; and
a fourth control signal coupled to gates of the fourth and fifth switching transistors, the fourth control signal being complimentary to the third control signal.

2. The tap circuit of claim 1, wherein the correction source is a current source.

3. The tap circuit of claim 1, wherein the first power supply voltage is a ground.

4. The tap circuit of claim 3, wherein the first through sixth switching transistors are NMOS transistors.

5. The tap circuit of claim 1, wherein the first power supply voltage is a high voltage power supply (VDD).

6. The tap circuit of claim 5, wherein the first through sixth switching transistors are PMOS transistors.

7. The tap circuit of claim 1, wherein the first and second control signals are generated by the DFE circuit and the third and fourth control signals are generated by a DFE logic circuit.

8. The tap circuit of claim 1, wherein the first and second control signals are generated by a DFE logic circuit and the third and fourth control signals are generated by the DFE circuit.

9. A tap circuit in a summer of a decision feedback equalizer (DFE), the tap circuit comprising:
a first and a second net carrying a differential pair of received signals;
a current source coupled between a first node and a first power supply voltage, the current source having a magnitude being substantially proportional to a tap weight;
a first switching transistor with a source and a drain coupled between the first node and a second node, respectively;
a second switching transistor with a source and a drain coupled between the first node and a third node, respectively;
a third switching transistor with a source and a drain coupled between the second node and the first net, respectively;
a fourth switching transistor with a source and drain coupled between the second node and the second net, respectively;
a fifth switching transistor with a source and drain coupled between the third node and the first net, respectively;
a sixth switching transistor with a source and drain coupled between the third node and the second net, respectively;
a first and second control signals coupled to gates of the first and second switching transistors, respectively, the first and second control signal being complimentary to each other;
a third control signal coupled to gates of the third and sixth switching transistors; and
a fourth control signal coupled to gates of the fourth and fifth switching transistors, the fourth control signal being complimentary to the third control signal.

10. The tap circuit of claim 9, wherein the first power supply voltage is a ground.

11. The tap circuit of claim 10, wherein the first through sixth switching transistors are NMOS transistors.

12. The tap circuit of claim 9, wherein the first power supply voltage is a high voltage power supply (VDD).

13. The tap circuit of claim 12, wherein the first through sixth switching transistors are PMOS transistors.

14. The tap circuit of claim 9, wherein the first and second control signals are generated by the DFE circuit and the third and fourth control signals are generated by a DFE logic circuit.

15. The tap circuit of claim 9, wherein the first and second control signals are generated by a DFE logic circuit and the third and fourth control signals are generated by the DFE circuit.

16. A tap circuit in a summer of a decision feedback equalizer (DFE), the tap circuit comprising:
a first and a second net carrying a differential pair of received signals;
a correction source coupled between a first node and a ground, the correction source having a magnitude being substantially proportional to a tap weight;
a first NMOS transistor with a source and a drain coupled between the first node and a second node, respectively;
a second NMOS transistor with a source and a drain coupled between the first node and a third node, respectively;
a third NMOS transistor with a source and a drain coupled between the second node and the first net, respectively;
a fourth NMOS transistor with a source and drain coupled between the second node and the second net, respectively;
a fifth NMOS transistor with a source and drain coupled between the third node and the first net, respectively;
a sixth NMOS transistor with a source and drain coupled between the third node and the second net, respectively;
a first and second control signals coupled to gates of the first and second NMOS transistors, respectively, the first and second control signal being complimentary to each other;
a third control signal coupled to gates of the third and sixth NMOS transistors; and
a fourth control signal coupled to gates of the fourth and fifth NMOS transistors, the fourth control signal being complimentary to the third control signal.

17. The tap circuit of claim 16, wherein the correction source is a current source.

18. The tap circuit of claim 16, wherein the first and second control signals are generated by the DFE circuit and the third and fourth control signals are generated by a DFE logic circuit.

19. The tap circuit of claim 16, wherein the first and second control signals are generated by a DFE logic circuit and the third and fourth control signals are generated by the DFE circuit.
